(19) United States
(12) Patent Application Publication
(10) Pub. No.: US 2013/0288469 A1
(43) Pub. Date: Oct. 31, 2013

(54) METHODS AND APPARATUS FOR IMPLANTING A DOPANT MATERIAL

(71) Applicant: APPLIED MATERIALS, INC., Santa Clara, CA (US)

(72) Inventors: SHASHANK SHARMA, San Jose, CA (US); MARTIN A. HILKENE, Gilroy, CA (US); MATTHEW SCOTNEY-CASTLE, Morgan Hill, CA (US); JOHN BOLAND, Scotts Valley, CA (US)

(73) Assignee: APPLIED MATERIALS, INC., Santa Clara, CA (US)

(21) Appl. No.: 13/861,914

(22) Filed: Apr. 12, 2013

Related U.S. Application Data
(60) Provisional application No. 61/639,398, filed on Apr. 27, 2012.

(51) Int. Cl. H01L 21/265

(52) U.S. Cl. CPC H01L 21/265
USPC 438/527

(57) ABSTRACT

Methods and apparatus for implanting a dopant material are provided herein. In some embodiments, a method of processing a substrate disposed within a process chamber may include (a) implanting a dopant material into a surface of the substrate to form a doped layer in the substrate and an elemental dopant layer atop the doped layer; (b) removing at least some of the elemental dopant layer from atop the surface of the substrate; and (c) implanting the dopant material into the doped layer of the substrate; wherein (a)-(c) are performed without removing the substrate from the process chamber; and wherein (a)-(c) are repeated until at least one of a desired dopant implantation depth or a desired dopant implantation density is achieved.

### CROSS-REFERENCE TO RELATED APPLICATIONS

This application claims benefit of U.S. provisional patent application Ser. No. 61/639,398, filed Apr. 27, 2012, which is herein incorporated by reference in its entirety.

### FIELD

Embodiments of the present invention generally relate to semiconductor processing equipment and techniques.

### BACKGROUND

The inventors have observed that doping processes for typical dopant materials used in the semiconductor industry often leads to metallurgical junction formation into a substrate. In addition to the junction, the doping process leads to the deposition of an elemental dopant layer on the top of the substrate. The elemental dopant layer acts as a screening layer to limit the penetration of dopant materials into the substrate and affects the conformality of the doping process.

As such, the inventors have provided improved methods and apparatus for implanting a dopant material into a substrate.

### SUMMARY

Methods and apparatus for implanting a dopant material are provided herein. In some embodiments, a method of processing a substrate disposed within a process chamber includes (a) implanting a dopant material into a surface of the substrate to form a doped layer in the substrate and an elemental dopant layer atop the doped layer; (b) removing at least some of the elemental dopant layer from atop the surface of the substrate; and (c) implanting the dopant material into the doped layer of the substrate; wherein (a)-(c) are performed without removing the substrate from the process chamber.

In some embodiments, a method of processing a substrate includes (a) disposing a substrate within a plasma ion implantation chamber; (b) implanting a dopant material into a surface of the substrate to form a doped layer in the substrate and an elemental dopant layer atop the surface of the substrate; (c) removing at least a portion of the elemental dopant layer; (d) implanting the dopant material into the doped layer of the substrate, wherein (b)-(d) are performed without removing the substrate from the plasma ion implantation chamber; and repeating (b)-(d) until at least one of a desired dopant implantation depth or a desired dopant implantation density is achieved.

In some embodiments, a computer readable medium is provided, having instructions stored thereon that, when executed, cause any of the methods as described herein to be performed.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart for a method of implanting a dopant material in accordance with some embodiments of the present invention.

FIGS. 2A-2E depict the stages of fabrication of implanting a dopant material in accordance with some embodiments of the present invention.

FIG. 3 depicts a schematic view of a plasma immersion ion implantation process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide improved methods and apparatus for implanting a dopant material into a substrate. Embodiments of the present invention may advantageously reduce substrate non-uniformity caused by plasma doping with dopants such as boron, arsenic, phosphorus, and the like. Exemplary, but non-limiting, examples of target applications for the inventive methods disclosed herein may include high dose plasma doping and conformal doping applications.

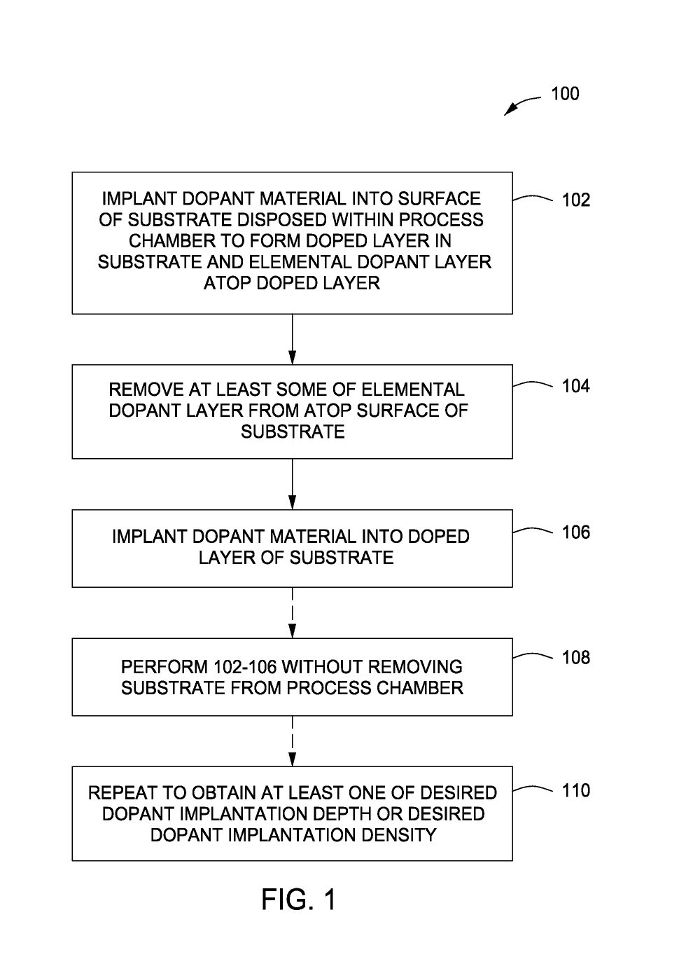

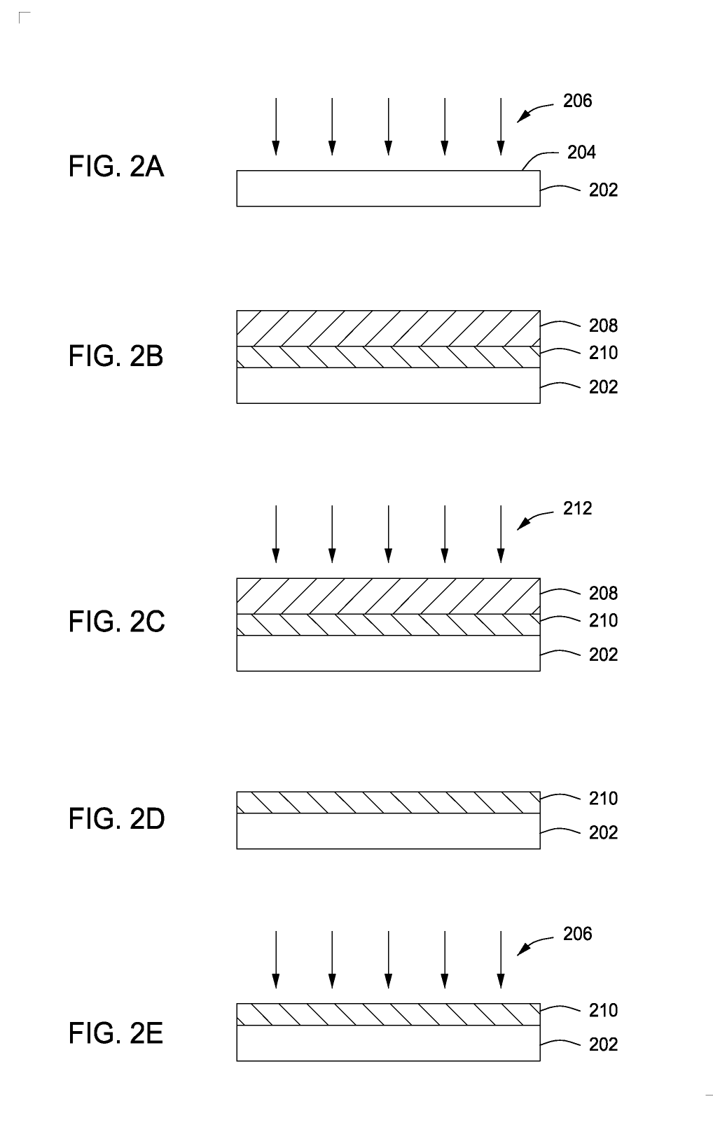

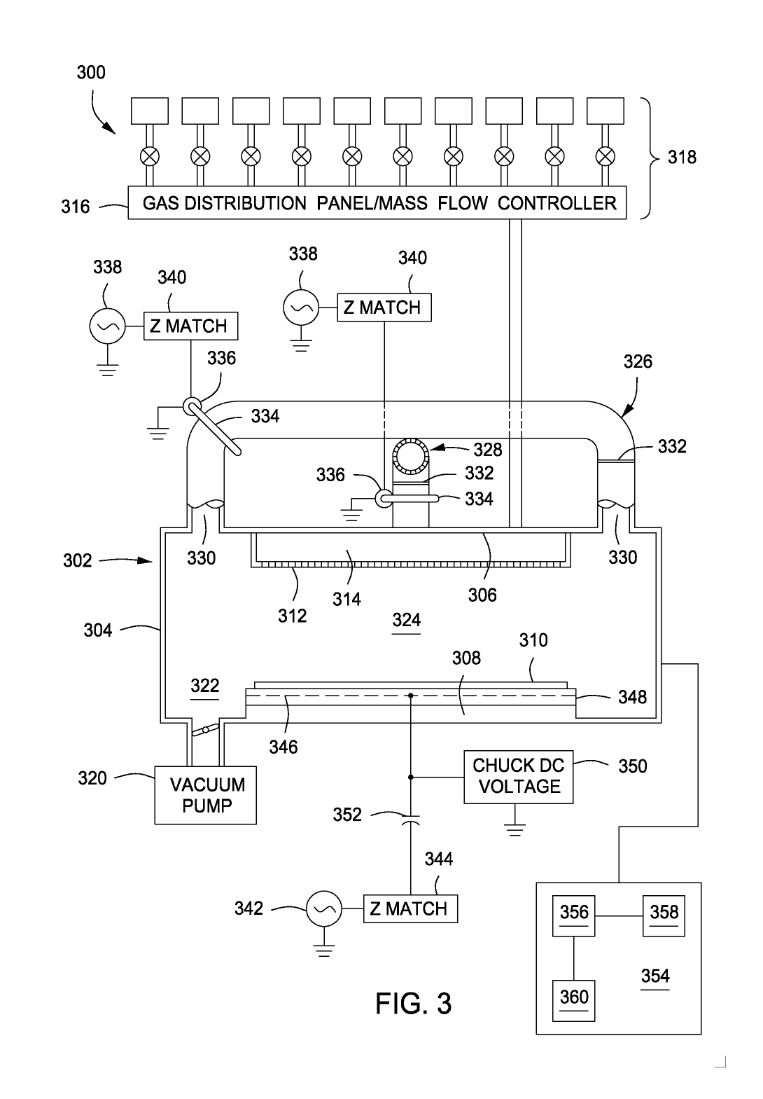

FIG. 1 depicts a flow chart for a method 100 of implanting a dopant species into a substrate. The method 100 is described below in accordance with a series of fabrication steps illustrated in FIGS. 2A-2E. In some embodiments, at least some portions of the method 100 may be performed in a toroidal source plasma ion immersion implantation reactor, for example, such as the reactor 300 described below with respect to FIG. 3 (although other suitable process chambers may alternatively be used).

The method 100 generally begins at 102 where a dopant material 206 is implanted into a surface 204 of a substrate 202, as illustrated in FIG. 2A. In some embodiments, the substrate to be doped may comprise any suitable material or materials used in the fabrication of semiconductor devices. For example, in some embodiments, the substrate may comprise a semiconducting material and/or combinations of semiconducting materials and non-semiconducting materials for forming semiconductor structures and/or devices. The substrate may further comprise multiple layers. For example, the substrate may comprise one or more silicon-containing materials such as crystalline silicon (e.g., Si<100> or Si<111>), silicon oxide, strained silicon, polysilicon, silicon wafers, glass, sapphire, or the like. The substrate may further have any desired geometry, such as a 200 or 300 mm wafer, square or rectangular panels, or the like. In some embodiments, the substrate may be a semiconductor wafer (e.g., a 200 mm, 300 mm, 450 mm, silicon wafer, or the like). In some embodiments, the substrate may have 3-dimensional (“3D”) semiconductor structures, such as a FinFET device or the like.

When doping the substrate 202, the entire surface of the substrate may be doped, or if select regions of the substrate are to be doped, a patterned mask layer, such as a patterned photoresist layer, may be deposited atop the substrate to protect regions of the substrate that are not to be doped. For example, in some embodiments, a masking layer, such as a layer of photoresist, may be provided and patterned such that the doped region is formed only on portions of the substrate.

The dopant species 206 may comprise any suitable element or elements typically used in semiconductor doping processes. Examples of suitable dopants include, in a non-limiting example, carbon (C), arsenic (As), boron (B), phosphorous (P), or the like.

The doped region may be formed by implanting one or more dopants into the substrate in an implantation process, such as a plasma assisted implantation process. The doping process may be performed in any suitable doping chamber, such as a plasma-assisted doping chamber. For example, embodiments of the present invention may be performed in a toroidal source plasma ion immersion implantation reactor such as described below with respect to FIG. 3.

The inventors have observed that dopant implantation processes may result in the formation of an elemental dopant layer 208 atop the dopant-implanted surface 210 of the substrate 202 as depicted in FIG. 2B. Left alone, the elemental dopant layer 208 may undesirably cause process non-uniformities. For example, the elemental dopant layer 208 may undesirably act as a screening layer that limits further ion penetration of the one or more dopants into the substrate 202. Therefore, at 104, at least some of the elemental dopant layer 208 is removed from atop the dopant-implanted surface 210 of the substrate 202. In some embodiments, the removal process may be performed in-situ, i.e., in the same chamber as the doping process and without removal of the substrate from the chamber.

In some embodiments, as depicted in FIG. 2C, the elemental dopant layer 208 is impinged with a sputtering material 212 to remove at least some of the elemental dopant layer 208. In some embodiments, the sputtering material 212 may be at least one of argon (Ar), helium (H), xenon (X), or the like. Alternatively or in combination, in some embodiments, the elemental dopant layer 208 may be exposed to an etchant gas, such as at least one of nitrogen trifluoride (NF₃), chlorine (Cl₂), hydrogen (H₂), or hydrogen chloride (HCl) to remove the elemental dopant layer 208.

In some embodiments, as depicted in FIG. 2D, substantially all of the elemental dopant layer 208 is removed to expose most or all of the dopant-implanted surface 210 of the substrate 202. Alternatively, in some embodiments, a portion of the elemental dopant layer 208 may be removed without exposing the dopant-implanted surface 210 of the substrate 202. In embodiments where a patterned mask layer is used to protect portions of the substrate 202, the elemental dopant layer 208 is removed to expose some or all of the dopant-implanted surface 210 of the substrate 202 in the regions defined by the patterned mask layer.

Next, at 106, the dopant material 206 is implanted into the doped layer 210 of a substrate 202, as illustrated in FIG. 2E. The dopant material 206 may be implanted into the doped layer 210 in the same manner as the dopant material 206 is deposited in to the surface 204 of the substrate 202, as discussed above. Thus, in some embodiments, and as noted at 108, the above method as described with respect to 102, 104, and 106 may advantageously be performed in the same process chamber without removing the substrate from the process chamber. This advantageously improves the efficiency of the implantation process by reducing the time needed to transfer the substrate between different process chambers.

In some embodiments, as indicated at 110, the method described with respect to 104-108 may be repeated until at least one of a desired dopant implantation depth or a desired dopant implantation density is achieved. For example, similar to as discussed above with respect to 102, the implantation of the dopant material 206 into the doped layer 210 at 106 may also result in the formation of an elemental dopant layer. This elemental dopant layer is essentially the same as the elemental dopant layer 208 and may be formed atop any remaining elemental dopant layer 208 or, where the elemental dopant layer 208 was previously completely removed, may result in the formation of a new elemental dopant layer 208.

In some embodiments, the cyclic process may end after a final implantation of the one or more dopant species. In some embodiments, the cyclic process may end after a final removal of at least some of the elemental dopant layer. The inventors have discovered that repetition of the method described above advantageously leads to refreshed dopant implanted surfaces, free of the elemental dopant layer, between each implantation cycle. As a result, the conformality of the doping process is enhanced.

Thus, in some embodiments, a cyclic process comprising repeated cycles of plasma immersion ion implantation and in-situ cleans may be performed. The in-situ clean removes at least some of the deposited elemental dopant layer (e.g., 208) and hence refreshes the wafer surface between each implant process leading to higher implanted doses in the dopant layer (e.g., 210). The inventors have experimentally confirmed the cyclic process described above to result, in at least some embodiments, in implanted dose enhancement of at least an order of magnitude. This high dose doping capability advantageously enables conformal doping for next generation semiconductor devices like FinFETs.

Embodiments of the present invention may be performed in toroidal source plasma ion immersion implantation reactor such as, but not limited to, the CONFORMA™ reactor commercially available from Applied Materials, Inc., of Santa Clara, Calif. Such a suitable reactor and its method of operation are set forth in U.S. Pat. No. 7,166,524, assigned to the assignee of the present invention.

Referring to FIG. 3, a toroidal source plasma immersion ion implantation reactor 300 of the type disclosed in the above-reference application has a cylindrical vacuum chamber 302 defined by a cylindrical side wall 304 and a disk-shaped ceiling 306. A substrate support pedestal 308 at the floor of the chamber supports a substrate 310 to be processed. A gas distribution plate or showerhead 312 on the ceiling 306 receives process gas in its gas manifold 314 from a gas distribution panel 316 whose gas output can be any one of or mixtures of gases from one or more individual gas supplies 318. A vacuum pump 320 is coupled to a pumping annulus 322 defined between the substrate support pedestal 308 and the sidewall 304. A processing region 324 is defined between the substrate 310 and the gas distribution plate 312.

A pair of external reentrant conduits 326, 328 establishes reentrant toroidal paths for plasma currents passing through the processing region 324, the toroidal paths intersecting in the processing region 324. Each of the conduits 326, 328 has a pair of ends 330 coupled to opposite sides of the chamber. Each conduit 326, 328 is a hollow conductive tube. Each conduit 326, 328 has a D.C. insulation ring 332 preventing the formation of a closed loop conductive path between the two ends of the conduit.

An annular portion of each conduit 326, 328, is surrounded by an annular magnetic core 334. An excitation coil 336 surrounding the core 334 is coupled to an RF power source 338 through an impedance match device 340. The two RF power sources 338, coupled to respective excitation coils 336 of the cores 334, may be of two slightly different frequencies. The RF power coupled from the RF power generators 338 produces plasma ion currents in closed toroidal paths extending through the respective conduit 326, 328 and through the processing region 324. These ion currents oscillate at the frequency of the respective RF power source 338. Bias power is applied to the substrate support pedestal 308 by a bias power generator 342 through an impedance match circuit 344.

Plasma formation is performed by introducing a process gas, or mixture of process gases into the chamber 324 through the gas distribution plate 312 and applying sufficient source power from the generators 338 to the reentrant conduits 326, 328 to create toroidal plasma currents in the conduits and in the processing region 324. The plasma flux proximate the wafer surface is determined by the wafer bias voltage applied by the RF bias power generator 342. The plasma rate or flux (number of ions sampling the wafer surface per square cm per second) is determined by the plasma density, which is controlled by the level of RF power applied by the RF source power generators 338. The cumulative ion dose (ions/square cm) at the wafer 310 is determined by both the flux and the total time over which the flux is maintained.

If the wafer support pedestal 308 is an electrostatic chuck, then a buried electrode 346 is provided within an insulating plate 348 of the wafer support pedestal, and the buried electrode 346 is coupled to a user-controllable D.C. chucking voltage supply 350 and to the bias power generator 342 through the impedance match circuit 344 and through an optional isolation capacitor 352 (which may be included in the impedance match circuit 344).

In operation, and for example, the substrate 310 may be placed on the substrate support pedestal 308 and one or more process gases may be introduced into the chamber 302 to strike a plasma from the process gases.

In operation, a plasma may be generated from the process gases within the reactor 300 to selectively modify surfaces of the substrate 310 as discussed above. The plasma is formed in the processing region 324 by applying sufficient source power from the generators 338 to the reentrant conduits 326, 328 to create plasma ion currents in the conduits 326, 328 and in the processing region 324 in accordance with the process described above. In some embodiments, the wafer bias voltage delivered by the RF bias power generator 342 can be adjusted to control the flux of ions to the wafer surface, and possibly one or more of the thickness of a layer formed on the wafer or the concentration of plasma species embedded in the wafer surface. In some embodiments, no bias power is applied.

A controller 354 comprises a central processing unit (CPU) 356, a memory 358, and support circuits 360 for the CPU 356 and facilitates control of the components of the chamber 302. To facilitate control of the process chamber 302, the controller 354 may be one of any form of general-purpose computer processor that can be used in an industrial setting for controlling various chambers and sub-processors. The memory 358, or computer-readable medium, of the CPU 356 may be one or more of readily available memory such as random access memory (RAM), read only memory (ROM), floppy disk, hard disk, or any other form of digital storage, local or remote. The support circuits 360 are coupled to the CPU 356 for supporting the processor in a conventional manner. These circuits include cache, power supplies, clock circuits, input/output circuitry and subsystems, and the like. The inventive methods, or at least portions thereof, described herein may be stored in the memory 358 as a software routine. The software routine may also be stored and/or executed by a second CPU (not shown) that is remotely located from the hardware being controlled by the CPU 356.

Thus, improved apparatus for depositing films on a substrate have been disclosed herein. The inventive apparatus may advantageously facilitate one or more of depositing films having reduced film non-uniformity within a given process chamber.

While the foregoing is directed to embodiments of the present invention, other and further embodiments of the invention may be devised without departing from the basic scope thereof.

1. A method of processing a substrate disposed within a process chamber, comprising:
(a) implanting a dopant material into a surface of the substrate to form a doped layer in the substrate and an elemental dopant layer atop the doped layer;
(b) removing at least some of the elemental dopant layer from atop the surface of the substrate; and
(c) implanting the dopant material into the doped layer of the substrate after removing at least some of the elemental dopant layer;
wherein (a)-(c) are performed without removing the substrate from the process chamber.

2. The method of claim 1, wherein removing at least some of the elemental dopant layer further comprises:
impinging the elemental dopant layer with a sputtering material to remove at least some of the elemental dopant layer.

3. The method of claim 2, wherein the sputtering material comprises at least one of argon, helium, or xenon.

4. The method of claim 1, wherein removing at least some of the elemental dopant layer further comprises:
exposing the elemental dopant layer to an etchant gas to remove at least some of the elemental dopant layer.

5. The method of claim 4, wherein the etchant gas comprises at least one of nitrogen trifluoride (NF₃), chlorine (Cl₂), hydrogen (H₂), or hydrogen chloride (HCl).

6. The method of claim 1, wherein removing at least some of the elemental dopant layer further comprises:
removing substantially all of the elemental dopant layer to expose the surface of the dopant-implanted substrate.

7. The method of claim 1, wherein removing at least some of the elemental dopant layer further comprises:
removing a portion of the elemental dopant layer without exposing an underlying surface of the dopant-implanted substrate.

8. The method of claim 1, further comprising:
repeating (b)-(c) until at least one of a desired dopant implantation depth or a desired dopant implantation density is achieved.

9. The method of claim 1, wherein implanting the dopant material into the surface of the substrate further comprises:
controlling at least one of a bias voltage, a dopant gas flow, or a process chamber pressure to control at least one of the dopant implantation depth or dopant implantation density of the dopant material into the substrate.

10. The method of claim 1, wherein the dopant material comprises at least one of boron, arsenic, phosphorous, or carbon.

11. A method of processing a substrate, comprising:
(a) disposing a substrate within a plasma ion implantation chamber;
(b) implanting a dopant material into a surface of the substrate to form a doped layer in the substrate and an elemental dopant layer atop the surface of the substrate;
(c) removing at least a portion of the elemental dopant layer;
(d) implanting the dopant material into the doped layer of the substrate after removing at least some of the elemental dopant layer, wherein (b)-(d) are performed without removing the substrate from the plasma ion implantation chamber; and
repeating (c)-(d) until at least one of a desired dopant implantation depth or a desired dopant implantation density is achieved.

12. The method of claim 11, wherein removing the elemental dopant layer further comprises:
impinging the elemental dopant layer with a sputtering material to remove at least some of the elemental dopant layer.

13. The method of claim 11, wherein removing the elemental dopant layer further comprises:
exposing the elemental dopant layer to an etchant gas to remove at least some of the elemental dopant layer.

14. The method of claim 11, wherein removing the elemental dopant layer further comprises:
removing substantially all of the elemental dopant layer to expose the surface of the dopant-implanted substrate.

15. The method of claim 11, wherein removing the elemental dopant layer further comprises:
removing a portion of the elemental dopant layer without exposing the surface of the dopant-implanted substrate.

16. A computer readable medium, having instructions stored thereon that, when executed, cause a method of method of processing a substrate disposed within a process chamber to be performed, the method comprising:
(a) implanting a dopant material into a surface of the substrate to form a doped layer in the substrate and an elemental dopant layer atop the doped layer;
(b) removing at least some of the elemental dopant layer from atop the surface of the substrate; and
(c) implanting the dopant material into the doped layer of the substrate after removing at least some of the elemental dopant layer;
wherein (a)-(c) are performed without removing the substrate from the process chamber.

17. The computer readable medium of claim 16, wherein removing the elemental dopant layer further comprises:
impinging the elemental dopant layer with a sputtering material to remove at least some of the elemental dopant layer.

18. The computer readable medium of claim 16, wherein removing the elemental dopant layer further comprises:
exposing the elemental dopant layer to an etchant gas to remove at least some of the elemental dopant layer.

19. The computer readable medium of claim 16, wherein removing the elemental dopant layer further comprises:
removing substantially all of the elemental dopant layer to expose the surface of the dopant-implanted substrate.

20. The computer readable medium of claim 16, wherein removing the elemental dopant layer further comprises:
removing a portion of the elemental dopant layer without exposing the surface of the dopant-implanted substrate.
